(19) United States
(12) Patent Application Publication
(10) Pub. No.: US 2026/0251680 A1
(43) Pub. Date: Aug. 27, 2026

(54) ELECTRICAL CONNECTION DEVICE, ALIGNMENT MARK USED FOR MANUFACTURING ELECTRICAL CONNECTION DEVICE, AND METHOD OF MANUFACTURING ELECTRICAL CONNECTION DEVICE

(71) Applicant: KABUSHIKI KAISHA NIHON MICRONICS, Tokyo (JP)

(72) Inventors: Yoshitaka YAGIHASHI, Aomori (JP); Osamu KUMAZAWA, Aomori (JP); Hironori SASADA, Aomori (JP)

(73) Assignee: KABUSHIKI KAISHA NIHON MICRONICS, Tokyo (JP)

(21) Appl. No.: 19/535,168

(22) Filed: Feb. 10, 2026

(30) Foreign Application Priority Data
Feb. 25, 2025 (JP) 2025-027957

(51) Int. Cl. G01R 1/073

(52) U.S. Cl. CPC G01R 1/07342

(57) ABSTRACT

An electrical connection device 1 includes a probe, a substrate, a probe pad, and an alignment mark. The probe pad has a structure in which a first pad layer and a second pad layer are laminated and is arranged on the substrate. The alignment mark has a structure in which a first alignment mark layer and a second alignment mark layer are laminated and is arranged on the substrate separately from the probe pad. The first alignment mark layer and the second alignment mark layer have similar shapes when viewed from the lamination direction in which the first alignment mark layer and the second alignment mark layer are laminated, and an outer edge of the first alignment mark layer is located inside an outer edge of the second alignment mark layer.

### CROSS-REFERENCE TO RELATED APPLICATIONS

The present application is based upon, and claims the benefit of priority from Japanese Patent Application No. 2025-027957, filed on February 25, 2025, the entire contents of which are incorporated herein by reference.

### TECHNICAL FIELD

The present invention relates to an electrical connection device used for inspecting electrical characteristics of an inspection object, alignment mark used for manufacturing electrical connection device, and method of manufacturing electrical connection device.

### BACKGROUND

Electrical connection devices are used to inspect the electrical characteristics of an inspection object, such as a semiconductor integrated circuit, in a wafer state. The electrical connection device includes a probe that contacts the inspection object, and a substrate on which internal wiring electrically connected to the probe is arranged. When inspection using the probe, one end of the probe contacts the inspection object. The other end of the probe is arranged on a placement pad arranged on the substrate. The placement pad is electrically connected to an inspection device such as a tester through internal wiring of the substrate.

In order to arrange the probe on the placement pad, it is necessary to accurately align the substrate on which the placement pad is arranged and a bonding machine holding the probe for connection to the placement pad. Therefore, a manufacturing method is used in which an alignment mark is formed on the substrate and the bonding machine is aligned with respect to the substrate while referring to the alignment mark. Therefore, it is necessary to clearly see the shape of the alignment mark as a reference for alignment.

### SUMMARY

Placement pads are required to have mechanical strength and a certain thickness. Therefore, a laminated structure in which metal layers are stacked is used for placement pads. When an alignment mark is formed on a substrate at the same time as the placement pad, the alignment mark also has a laminated structure. An object of the invention is to provide an electrical connection device, an alignment mark used for manufacturing an electrical connection device, and a method of manufacturing the electrical connection device allowing clear visual recognition of the shape of the alignment mark of a structure in which metal layers are laminated.

An electrical connection device according to one aspect of the present invention includes a probe, a substrate, a probe pad, and an alignment mark. The probe pad has a structure in which a first pad layer and a second pad layer are laminated, and is arranged on the substrate. The alignment mark has a structure in which a first alignment mark layer and a second alignment mark layer are laminated, and is arranged on the substrate separately from the probe pad. The first alignment mark layer and the second alignment mark layer have similar shapes when viewed from a lamination direction in which the first alignment mark layer and the second alignment mark layer are laminated, and an outer edge of the first alignment mark layer is located inside an outer edge of the second alignment mark layer.

According to the present invention, it is possible to provide an electrical connection device, an alignment mark used for manufacturing the electrical connection device, and a method of manufacturing the electrical connection device allowing clear visual recognition of the shape of the alignment mark having a structure in which metal layers are laminated.

### BRIEF DESCRIPTION OF DRAWINGS

FIG. 1 is a schematic view illustrating a configuration of an electrical connection device according to an embodiment.

FIG. 2 is a schematic plan view illustrating a configuration of an electrical connection device according to an embodiment.

FIG. 3 is a schematic cross-sectional view of region A in FIG. 2.

FIG. 4 is a schematic plan view illustrating the shape of an alignment mark of an electrical connection device according to an embodiment.

FIG. 5 is a schematic cross-sectional view for explaining a method of manufacturing an electrical connection device according to an embodiment (part 1).

FIG. 6 is a schematic cross-sectional view for explaining a method of manufacturing an electrical connection device according to an embodiment (part 2).

FIG. 7 is a schematic cross-sectional view for explaining a method of manufacturing an electrical connection device according to an embodiment (part 3).

FIG. 8 is a schematic cross-sectional view for explaining a method of manufacturing an electrical connection device according to an embodiment (part 4).

FIG. 9 is a schematic cross-sectional view illustrating a method of manufacturing an electrical connection device according to an embodiment (Part 5).

FIG. 10 is a schematic cross-sectional view for explaining a method of manufacturing an electrical connection device according to an embodiment (Part 6).

FIG. 11 is a schematic plan view illustrating a structure of an alignment mark of Comparative Example1.

FIG. 12 is a cross-sectional view taken in a XII-XII direction in FIG. 11.

FIG. 13 is a schematic plan view illustrating a structure of an alignment mark of Comparative Example 2.

FIG. 14 is a cross-sectional view taken in a XIV-XIV direction in FIG. 13.

FIG. 15 is a schematic plan view illustrating problems arising in the alignment mark of Comparative Example 2.

### DESCRIPTION OF EMBODIMENTS

Embodiments of the present invention will now be described with reference to the accompanying drawings. In the following drawings, identical or similar parts are denoted by identical or similar reference signs. It should be noted, however, that the drawings are schematic, and the thickness ratio of parts is different from actual parts. In addition, it is needless to say that the drawings include parts in which the dimensional relationship and ratio are different from each other. The following embodiments exemplify a device and a method for embodying technical ideas of the present invention, and the embodiments of the present invention do not specify the material, shape, structure, arrangement, or the like of the components as follows.

### First Embodiment

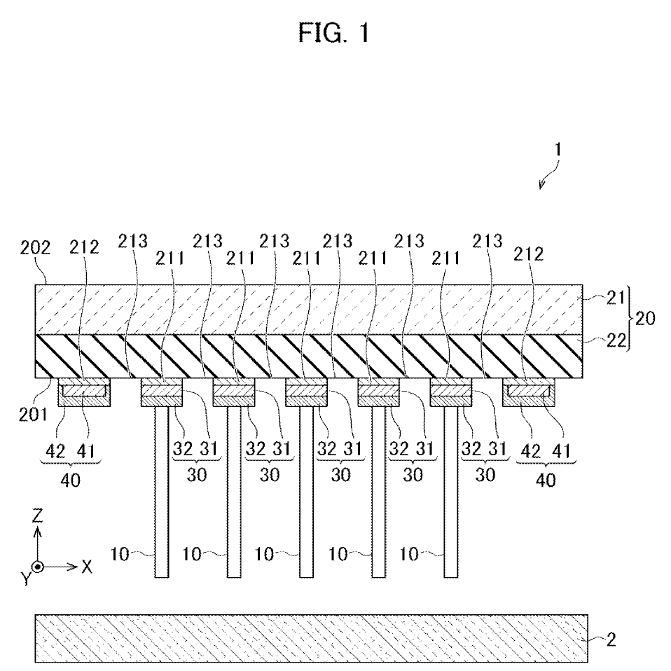

FIG. 1 illustrates an electrical connection device 1 according to the embodiment, which is used for inspecting the electrical characteristics of an inspection object 2. The electrical connection device 1 includes a probe 10, a substrate 20, a probe pad 30, and an alignment mark 40.

The substrate 20 includes a first surface 201 and a second surface 202 facing in an opposite direction to the first surface 201. A first region 211 and a second region 212 each having electric conductivity are formed on the first surface 201 separately from each other. The first region 211 and the second region 212 are surrounded by an insulation region 213. The substrate 20 includes internal wiring (not illustrated) electrically connected to the first region 211.

The substrate 20 may include a substrate (hereinafter referred to as “laminated substrate”.) in which a conductive layer and an insulation layers are laminated. For example, as illustrated in FIG. 1, the substrate 20 may include a laminated substrate 22 including the first surface 201, and a ceramic substrate 21 arranged on a main surface of the laminated substrate 22 facing in an opposite direction to the first surface 201. The insulation region 213 of the first surface 201 of the laminated substrate 22 may be formed, for example, as a resin layer. The laminated substrate 22 may have a laminated structure in which internal wirings are arranged on a plurality of wiring layers. The internal wirings arranged on the laminated substrate 22 and the internal wirings arranged on the ceramic substrate 21 are electrically connected.

The probe pad 30 is arranged in the first region 211 of the substrate 20. The probe pad 30 is a laminated structure having a first pad layer 31 connected to the first region 211 and a second pad layer 32 laminated on the first pad layer 31.

The probe 10 is arranged on the second pad layer 32 of the probe pad 30. Hereinafter, one end of the probe 10 facing the inspection object 2 is referred to as “tip end” and the other end of the probe 10 is referred to as “base end”. The base end of the probe 10 is electrically connected to the internal wiring of the substrate 20 via the probe pad 30.

The alignment mark 40 is arranged in the second region 212 of the substrate 20. The alignment mark 40 has a laminated structure including a first alignment mark layer 41 connected to the second region 212, and a second alignment mark layer 42 laminated on the first alignment mark layer 41.

In the description of the embodiment, in FIG. 1, the vertical direction is the Z direction, the horizontal direction is the X direction, and the depth direction is the Y direction. The direction in which the first alignment mark layer 41 and the second alignment mark layer 42 are, and the direction in which the first pad layer 31 and the second pad layer 32 are laminated, are both the Z direction, and the direction in which these layers are laminated is hereinafter also referred to as a “lamination direction”.

One end of the internal wiring of the substrate 20 is electrically connected to the probe pad 30, and the other end of the internal wiring of the substrate 20 is exposed on the second surface 202 of the substrate 20 on which the ceramic substrate 21 is exposed. The other end of the internal wiring exposed on the second surface 202 is connected to a terminal (not illustrated, and hereinafter referred to as “connection terminal”.) arranged on the second surface 202. In other words, the connection terminals of the probe pad 30 and the substrate 20 are electrically connected via the internal wiring.

A printed circuit board may be arranged on the second surface 202 of the substrate 20, and electrode terminals arranged on the printed circuit board and the connection terminal of the substrate 20 may be connected by an interposer. For example, a spring-type pogo pin may be used for the interposer. The electrode terminals arranged on the printed circuit board are electrically connected to an inspection device such as an IC tester via the wiring of the printed circuit board. By bringing the tip end of the probe 10 into contact with the inspection object 2, the inspection object 2 and the inspection device are electrically connected via the electrical connection device 1.

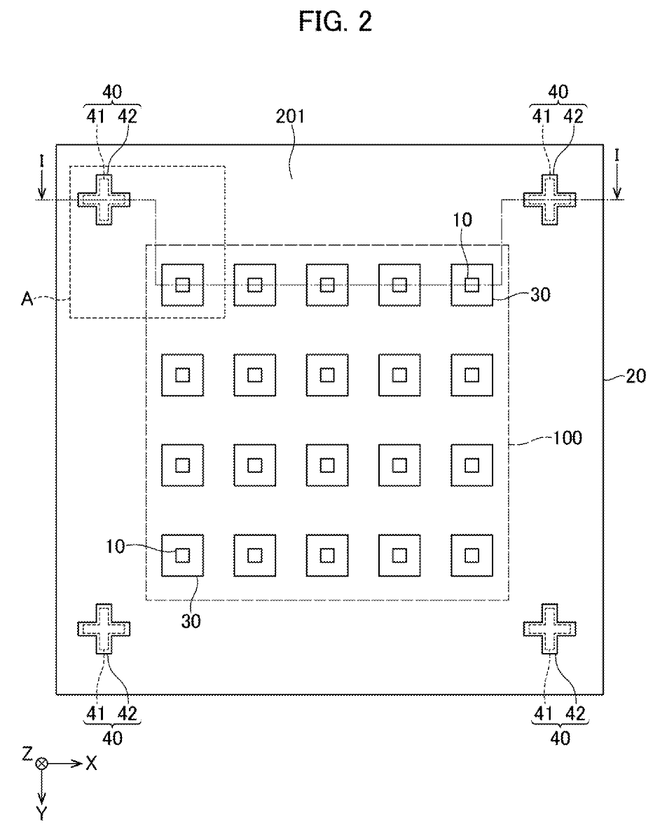

FIG. 2 is a view taken in the normal direction (Z direction) of the first surface 201. FIG. 1 is a cross-sectional view taken in an I-I direction of FIG. 2.

As illustrated in FIG. 2, the electrical connection device 1 may include a plurality of probe pads 30 arranged on the first surface 201 of the substrate 20. Hereinafter, a region of the first surface 201 in which the plurality of probe pads 30 are arranged will be referred to as a “probe arrangement region 100”. In the example illustrated in FIG. 2, the probe arrangement region 100 is set near a center of the first surface 201 of the substrate 20, which has a rectangular shape when viewed from the lamination direction.

For example, as illustrated in FIG. 2, the alignment mark 40 may be arranged on the first surface 201 in a peripheral region outside the probe arrangement region 100. In the example illustrated in FIG. 2, the alignment marks 40 are each arranged at four corners of the rectangular first surface 201.

In a configuration where the probes 10 are arranged on each of the plurality of probe pads 30, the laminated substrate 22 of the substrate 20 may include a space transformer. The space transformer makes a space between the internal wirings of the ceramic substrate 21 electrically connected to each of the adjacent probes 10 larger than a space between the probe pads 30 to which the adjacent probes 10 are connected. In other words, by including the space transformer in the laminated substrate 22, the interval between the connection terminals of the substrate 20 and the electrode terminals of the printed circuit board can be made larger than the interval between the probe pads 30.

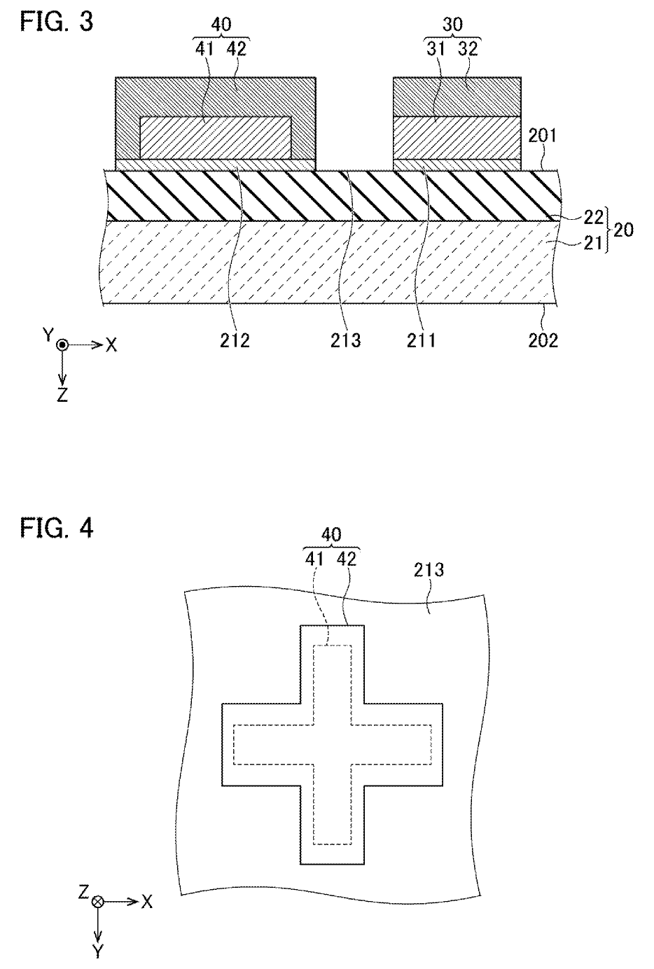

The alignment marks 40 are used for alignment in the step of joining the probes 10 to the probe pads 30 in manufacturing the electrical connection device 1, as will be described below. FIG. 3 illustrates a cross-sectional view of a region A in FIG. 2 including one probe pad 30 and one alignment mark 40. In FIG. 3, the probes 10 are not illustrated.

As illustrated in FIG. 3, the alignment mark 40 includes the first alignment mark layer 41 arranged in the second region 212 of the substrate 20, and the second alignment mark layer 42 laminated on the first alignment mark layer 41. When viewed from the lamination direction (hereinafter also referred to as “plan view”), the first alignment mark layer 41 and the second alignment mark layer 42 have similar shapes. Moreover, the outer edge of the first alignment mark layer 41 is located inside the outer edge of the second alignment mark layer 42. For example, as illustrated in FIG. 4, the first alignment mark layer 41 and the second alignment mark layer 42 may have a cross shape when viewed from the lamination direction. In FIG. 4, the first alignment mark layer 41 is displayed through the second alignment mark layer 42.

As illustrated in FIGS. 3 and 4, the second alignment mark layer 42 is formed to cover the first alignment mark layer 41, and the upper surface and the side surface of the first alignment mark layer 41 are covered with the second alignment mark layer 42. Further, the second region 212 and the second alignment mark layer 42 have the same shape when viewed from the lamination direction. Therefore, an insulation region 213 is exposed adjacent to the outer edge of the second alignment mark layer 42 in a plan view.

The first pad layer 31 and the second pad layer 32 have the same shape in a plan view when viewed from the lamination direction. In other words, the side surfaces of the first pad layer 31 and the second pad layer 32 are linearly continuous in the Z direction. The first pad layer 31 and the second pad layer 32 may have a rectangular shape when viewed from the lamination direction.

The material for the first pad layer 31 and the material for the second pad layer 32 may be the same. The material for the first alignment mark layer 41 and the material for the second alignment mark layer 42 may be the same. Further, the material for the first pad layer 31 and the material for the first alignment mark layer 41 may be the same, and the material for the second pad layer 32 and the material for the second alignment mark layer 42 may be the same. For example, material for the first alignment mark layer 41 and the second alignment mark layer 42 may be copper (Cu). Further, a nickel (Ni) layer and a gold (Au) layer may be sequentially laminated on the surface of the second alignment mark layer 42.

An example of a method of manufacturing the electrical connection device 1 using the alignment mark 40 according to the embodiment will be described below.

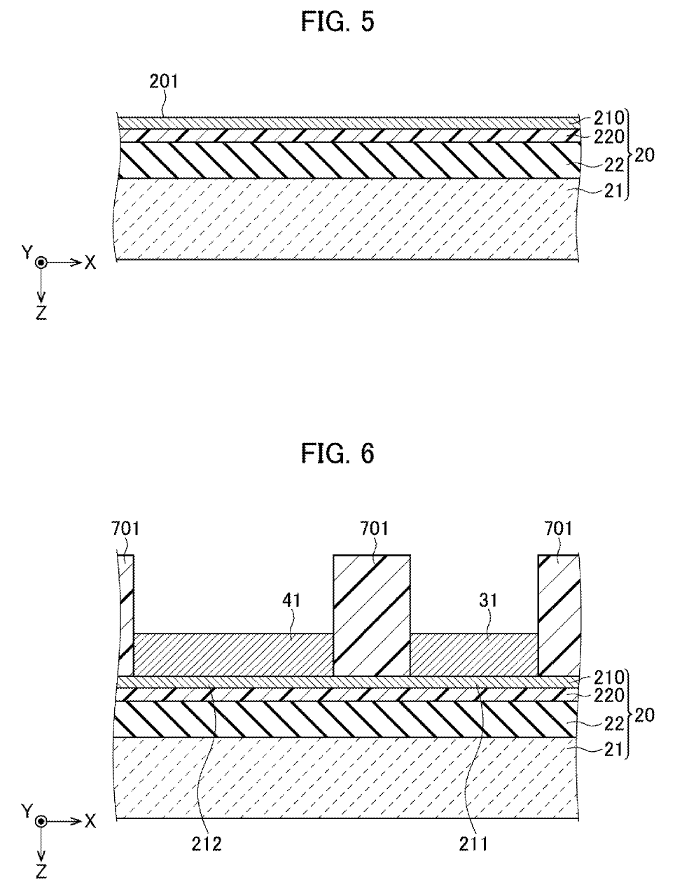

First, as illustrated in FIG. 5, the substrate 20 is prepared, in which a conductive layer 210 is laminated on an insulation layer 220, and is exposed as the first surface 201. The insulation layer 220 may be, for example, a resin layer.

Next, as will be described in detail later, the probe pad 30 is formed by laminating the first pad layer 31 and the second pad layer 32, and the alignment mark 40 is formed by laminating the first alignment mark layer 41 and the second alignment mark layer 42. The probe pad 30 is formed in the first region 211 of the first surface 201, and the alignment mark 40 is formed in the second region 212 of the first surface 201 separated from the first region 211. For example, the alignment mark 40 may have a cross shape in a plan view. The probe pad 30 may have a rectangular shape in a plan view.

More specifically, as illustrated in FIG. 6, a first photoresist film 701 is formed on the first surface 201, and is patterned so that the first region 211 where the first pad layer 31 is to be formed, and the second region 212 where the first alignment mark layer 41 is to be formed, are exposed. Then, the first pad layer 31 is formed in the first region 211, and the first alignment mark layer 41 is formed in the second region 212.

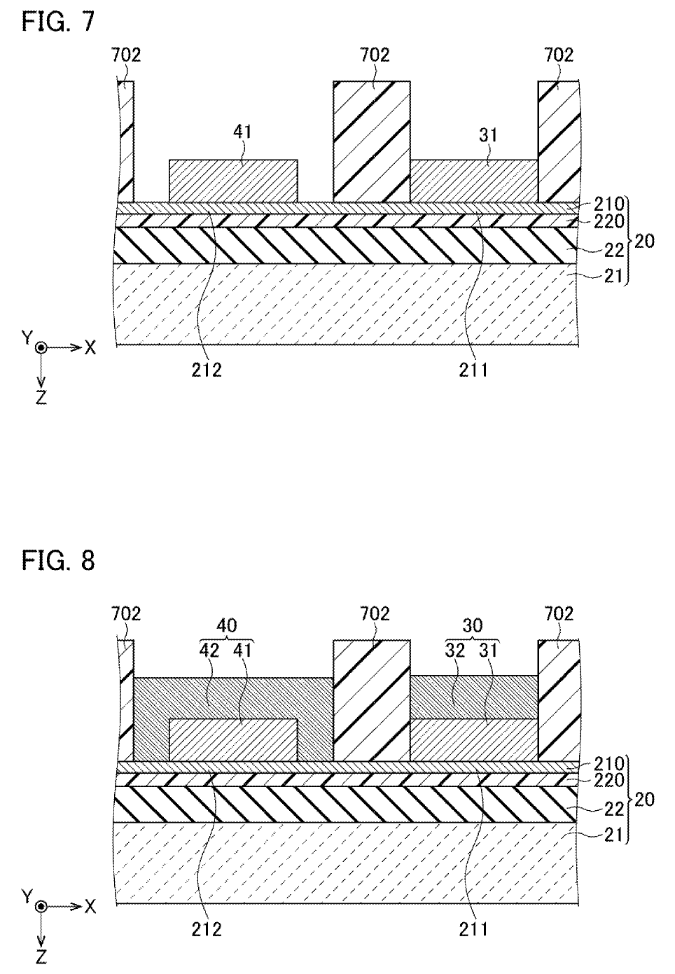

Then, after the first photoresist film 701 is removed, a second photoresist film 702 is formed on the first surface 201, as illustrated in FIG. 7, and the second photoresist film 702 is patterned so that an upper surface of the first pad layer 31, and an upper surface of the first alignment mark layer 41, are exposed. At this point, as illustrated in FIG. 7, the second photoresist film 702 is patterned so that the conductive layer 210 is exposed around an outer edge of the first alignment mark layer 41. Then, as illustrated in FIG. 8, the probe pad 30 is formed by laminating the second pad layer 32 on the first pad layer 31, and the alignment mark 40 is formed by laminating the second alignment mark layer 42 on the first alignment mark layer 41. Thus, the alignment mark 40 in which the outer edge of the first alignment mark layer 41 is located inside the outer edge of the second alignment mark layer 42 is formed.

As described above, the step of forming the probe pad 30 and the alignment mark 40 may include a stage of simultaneously forming the first pad layer 31 and the first alignment mark layer 41, and a stage of simultaneously forming the second pad layer 32 and the second alignment mark layer 42. That is, a first metal layer including the first pad layer 31 and the first alignment mark layer 41 is formed on the first surface 201 of the substrate 20. Then, a second metal layer, which includes a second pad layer 32 arranged on the upper surface of the first pad layer 31, and a second alignment mark layer 42 arranged on the upper surface of the first alignment mark layer 41, is laminated on the first metal layer. Thus, the first pad layer 31 and the first alignment mark layer 41 are arranged on the same plane level, and the second pad layer 32 and the second alignment mark layer 42 are arranged on the same plane level. The first metal layer and the second metal layer may be formed by copper plating, for example.

Alternatively, a nickel layer 51 and a gold layer 52 may be formed sequentially on the upper surface of the second metal layer. That is, the nickel layer 51 and the gold layer 52 may be laminated on the upper surfaces of the second pad layer 32 and the second alignment mark layer 42. By forming the gold layer 52 on the surface of the probe pad 30, contact resistance between the probe 10 and the probe pad 30 can be reduced. The nickel layer 51 serves as a barrier layer when the gold layer 52 is formed by plating.

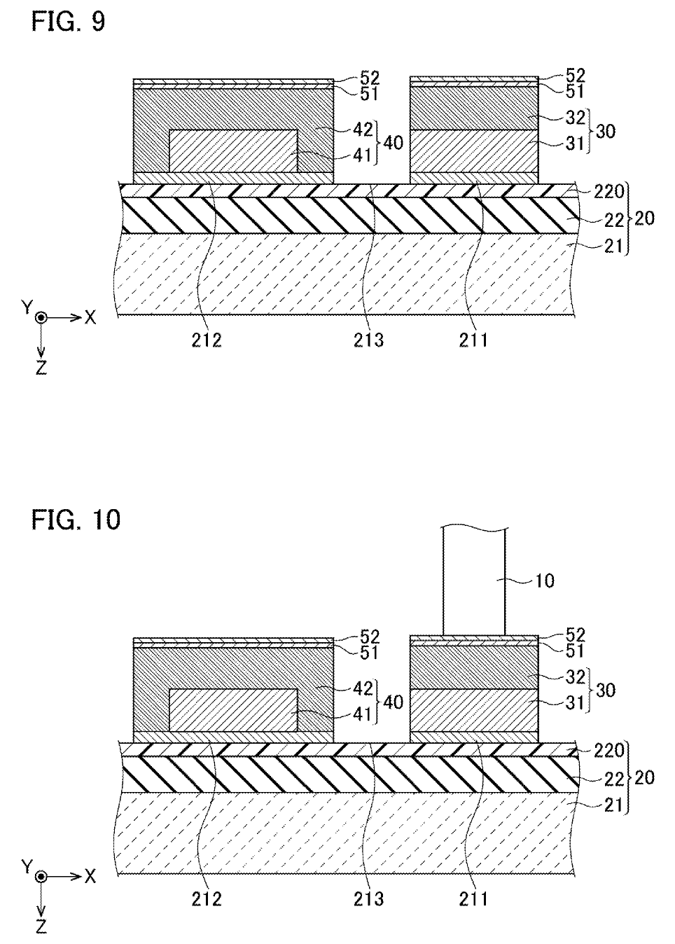

After the probe pad 30 and the alignment mark 40 are formed, the second photoresist film 702 is removed. Next, the conductive layer 210 is removed from a remaining region of the first surface 201 except the regions where the probe pad 30 and the alignment mark 40 are formed, and the insulation layer 220 is exposed, as illustrated in FIG. 9. The exposed surface of the insulation layer 220 is the insulation region 213.

In the alignment mark 40 formed in the steps above, the first alignment mark layer 41 and the second alignment mark layer 42 have similar shapes when viewed from the lamination direction, and the outer edge of the first alignment mark layer 41 is located inside the outer edge of the second alignment mark layer 42. Further, the second region 212 and the second alignment mark layer 42 have the same shape, viewed from the lamination direction, and the insulation layer 220 is exposed adjacent to the outer edge of the second alignment mark layer 42. The first pad layer 31 and the second pad layer 32 have the same shape, viewed from the lamination direction.

Thereafter, as illustrated in FIG. 10, the probe 10, which is to be connected to the inspection object 2, is arranged on the probe pad 30 using the alignment mark 40. For example, a bonding machine that holds the probe 10 is prepared to correspond to the position of the probe pad 30 on the first surface 201 of the substrate 20. Then, the substrate 20 and the probe 10 are aligned in the X direction and the Y direction with reference to the alignment mark 40. Then, the relative positions of the substrate 20 and the probe 10 are changed in the Z direction, the base end of the probe 10 is brought into contact with the probe pad 30, and the probe 10 is joined to the probe pad 30. For example, the base end of the probe 10 may be joined to the probe pad 30 by soldering. Thus, the electrical connection device 1 is completed.

The alignment of the probe 10 and the probe pad 30 is performed by visually observing the edge of the alignment mark 40. For example, in the case of the alignment mark 40 having a cross shape in a plan view, the corner portion of the alignment mark 40 at the intersection of a vertical axis and a horizontal axis of the cross shape may be used as a visual reference in the step of aligning the bonding machine and the substrate 20. In the step of joining the probe 10 to the probe pad 30, the alignment mark 40 is imaged by, for example, an imaging device installed on the bonding machine in a state where the bonding machine is superposed on the substrate 20, and it is visually confirmed that the cross shape is at a predetermined position. After confirming that the corner portion is at a predetermined position, the base end of the probe 10 is joined to the probe pad 30. In this manner, all of the probes 10 can be accurately joined to the probe pads 30. The position of the alignment mark 40 may be confirmed by automatic determination.

Before joining the base end of the probe 10 to the probe pad 30,an upper surface of the probe pad 30 may be polished to be planarized. For example, in FIG. 8, after planarization is performed so that the entire surfaces of the second photoresist film 702, the second pad layer 32, and the second alignment mark layer 42 are flush with each other, the second photoresist film 702 is removed, and the exposed conductive layer 210 is removed. Then, the second photoresist film 702 is formed again to planarize the entire surface, and then the nickel layer 51 and the gold layer 52 are vapor-deposited, and the second photoresist film 702 is removed. It is necessary that the probe pad 30 has a constant film thickness. However, the required film thickness cannot be formed with one layer due to the process capability, so that the probe pad 30 has a two-layer structure. The film thickness of the second layer, whose upper surface is polished for planarization, may be formed thicker than that of the first layer. Since the probe pad 30 has a two-layer structure, the alignment mark 40 formed simultaneously with the probe pad 30 also has a two-layer structure. In addition, since a heating step is performed after the step of forming the probe pad 30, the alignment mark 40 requires mechanical strength to prevent separation of the alignment mark 40 from the substrate 20. By forming the alignment mark 40 in a two-layer structure, the film thickness and mechanical strength of the alignment mark 40 can be secured. The film thickness of the probe pad 30 and the alignment mark 40 after completion may be, for example, about 20 μm to 35 μm.

In the following, an alignment mark of a comparative example will be described for comparison with the alignment mark 40 according to the embodiment.

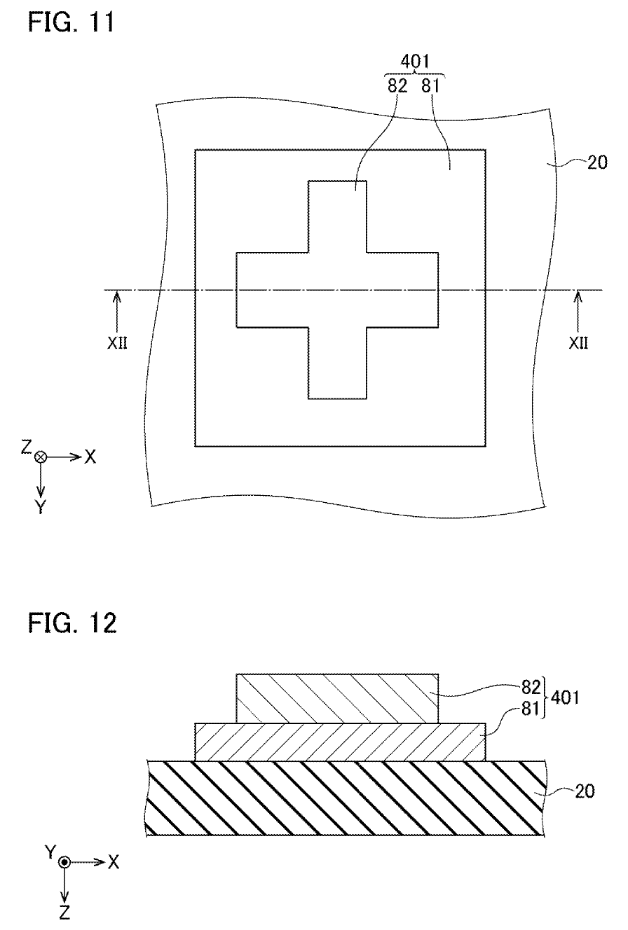

FIGS. 11 and 12 illustrate an alignment mark (hereinafter, referred to as “first comparative alignment mark 401”) of a first comparative example. The first comparative alignment mark 401 has a two-layer structure in which a first metal layer 81 and a second metal layer 82 are laminated. FIG. 11 is a top view of the first comparative alignment mark 401 , viewed from the lamination direction of the first metal layer 81 and the second metal layer 82. FIG. 12 is a cross-sectional view taken along a XII-XII direction in FIG. 11.

In the first comparative alignment mark 401, the first metal layer 81 has a rectangular shape, and the second metal layer 82 has a cross shape, in a plan view. In the alignment of the bonding machine in which the substrate 20 and the probe 10 are held, a cross shaped edge of the second metal layer 82 is used as a visual reference. Since the first metal layer 81 has a rectangular shape, a region of the upper surface of the first metal layer 81 that is not covered by the second metal layer 82 and is exposed exists around the second metal layer 82. The exposed region of the first metal layer 81 is discolored by, for example, oxidation. Therefore, it becomes difficult to identify the edge of the second metal layer 82 that has a cross shape.

In the alignment mark 40 according to the embodiment, the first alignment mark layer 41 and the second alignment mark layer 42 have similar shapes when viewed from the lamination direction, and the outer edge of the first alignment mark layer 41 is located inside the outer edge of the second alignment mark layer 42. Therefore, no region of the first alignment mark layer 41 is exposed. Therefore, in the alignment mark 40, discoloration of an exposed portion does not occur, so that difficulty in identifying the edge of the alignment mark 40 having a cross shape, for example, is prevented.

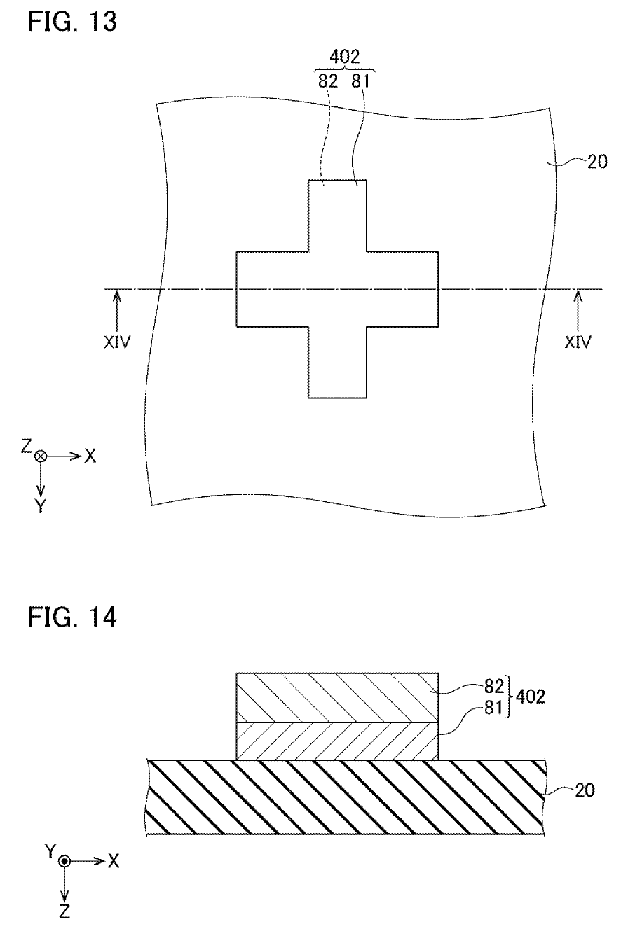

FIGS. 13 and 14 illustrate an alignment mark (hereinafter, referred to as “second comparative alignment mark 402”) of a second comparative example. The second comparative alignment mark 402 has a two-layer structure in which the first metal layer 81 and the second metal layer 82 are laminated. FIG. 13 is a top view of the second comparative alignment mark 402, viewed from the lamination direction. FIG. 14 is a cross-sectional view taken along a XIV-XIV direction of FIG. 13. In the second comparative alignment mark 402, the first metal layer 81 and the second metal layer 82 have the same cross shape in a plan view.

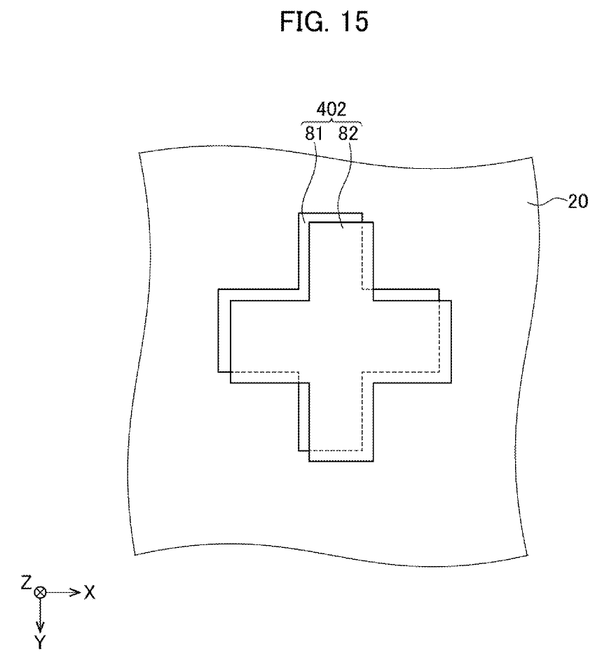

In the second comparative alignment mark 402, the edge of the cross shape become doubled, as illustrated in FIG. 15, when a positional shift occurs between the first metal layer 81 and the second metal layer 82 during manufacturing. As a result, it is difficult to identify the edges of the second comparative alignment mark 402 in the alignment of the bonding machine holding the substrate 20 and the probe 10.

In the alignment mark 40 according to the embodiment, the first alignment mark layer 41 and the second alignment mark layer 42 have similar shapes when viewed from the lamination direction, and the outer edge of the first alignment mark layer 41 is located inside the outer edge of the second alignment mark layer 42. That is, there is a difference in size (hereinafter referred to as “size difference”) between the first alignment mark layer 41 and the second alignment mark layer 42. Therefore, even if a deviation occurs in the overlap of the first alignment mark layer 41 and the second alignment mark layer 42, the first alignment mark layer 41 is covered by the second alignment mark layer 42 within a margin due to the size difference. Therefore, the outer edge of the second alignment mark layer 42 is visually recognized as an edge of the alignment mark 40. Therefore, in the alignment mark 40, doubled edges can be prevented.

The size difference between the first alignment mark layer 41 and the second alignment mark layer 42 may be set according to the manufacturing precision in the step of forming the alignment mark 40. That is, the size difference is set so that the first alignment mark layer 41 is covered by the second alignment mark layer 42 even when the overlap of the first alignment mark layer 41 and the second alignment mark layer 42 is deviated according to the precision of the manufacturing apparatus or the like. For example, the distance between the cross-shaped corners may be set to about 28 μm for the first alignment mark layer 41, and about 35 μm for the second alignment mark layer 42. Any size of the alignment mark 40 may be set as long as the edge can be identified.

Furthermore, in the alignment mark 40, the insulation region 213 is exposed adjacent to the outer edge of the second alignment mark layer 42. Therefore, the contrast between the alignment mark 40 and the periphery in a captured image is clearer than in the case where the metal layer is exposed to the outer edge of the second alignment mark layer 42 in a plan view, and the edge of the alignment mark 40 can be easily identified.

As described above, in the alignment mark 40, the first alignment mark layer 41 and the second alignment mark layer 42 have similar shapes when viewed from the lamination direction, and the outer edge of the first alignment mark layer 41 is located inside the outer edge of the second alignment mark layer 42. Therefore, in the alignment mark 40, the edge of the alignment mark 40 can be easily identified. Furthermore, by using the two-layer structure of the alignment mark 40, it is possible to maintain high visibility of the edge of the alignment mark 40, and to ensure a film thickness and mechanical strength. Then, it is possible to improve alignment accuracy of the probe 10 in the electrical connection device 1 manufactured using the alignment mark 40.

### Other Embodiments

The invention has been described in terms of embodiments as described above. However, the description and drawings which form part of this disclosure should not be understood as limiting the invention. Various alternative embodiments, examples, and techniques will become apparent to those skilled in the art from the disclosure.

The case where the alignment marks 40 are arranged at four corners of the rectangular first surface 201 of the substrate 20 has been described above by way of example. However, any number the alignment marks 40 and any location of the alignment marks 40 on the first surface 201 can be set. For example, the number and the location of the alignment marks 40 may be set according to the size of the substrate 20 or the accuracy of the manufacturing device.

As described above, it is obvious that the present invention includes embodiments which have not been described above.

1. An electrical connection device used for inspecting electrical characteristics of an inspection object, comprising:
a substrate including a first surface on which a first region and a second region, each having electric conductivity, are formed on a first surface, the first region and the second region being surrounded by an insulation region;
a probe pad arranged on the substrate and having a structure in which a first pad layer and a second pad layer are laminated;
a probe arranged on an upper surface of the second pad layer of the probe pad; and
an alignment mark having a structure in which a first alignment mark layer and a second alignment mark layer are laminated, and arranged in the second region of the substrate, wherein
the first alignment mark layer and the second alignment mark layer have similar shapes when viewed from a lamination direction in which the first alignment mark layer and the second alignment mark layer are laminated, and an outer edge of the first alignment mark layer is located inside an outer edge of the second alignment mark layer.

2. The electrical connection device according to claim 1, wherein
the second region and the second alignment mark layer have similar shapes when viewed from the lamination direction, and
the insulation region is exposed adjacent to an outer edge of the second alignment mark layer.

3. The electrical connection device according to claim 1, wherein the first pad layer and the second pad layer have the same shape when viewed from the lamination direction.

4. The electrical connection device according to claim 1, wherein
a probe arrangement region in which a plurality of the probe pads are arranged is set on the first surface, and
the alignment mark is arranged in a peripheral region outside the probe arrangement region.

5. The electrical connection device according to claim 4, wherein
the substrate has a rectangular shape when viewed from the lamination direction, and
the alignment marks are each arranged at four corners of the first surface.

6. The electrical connection device according to claim 1, wherein
the substrate includes a laminated substrate including the first surface, a ceramic substrate arranged on a main surface of the laminated substrate facing in an opposite direction to the first surface, and internal wirings electrically connected to the first region, and
the internal wirings arranged on the laminated substrate and the internal wirings arranged on the ceramic substrate are electrically connected.

7. The electrical connection device according to claim 6, further comprising a plurality of the probe pads arranged on the first surface, and a plurality of the probes each arranged on the plurality of probe pads, wherein
the laminated substrate includes a space transformer which makes a space between the internal wirings of the ceramic substrate electrically connected to each of the adjacent probes larger than a space between the probe pads to which the adjacent probes are connected.

8. An electrical connection device used for inspecting an electrical characteristic of an inspection object, comprising:
a substrate;
an alignment mark having a structure in which a first alignment mark layer and a second alignment mark layer are laminated, and arranged on the substrate; wherein
the first alignment mark layer and the second alignment mark layer have similar shapes when viewed from a lamination direction in which the first alignment mark layer and the second alignment mark layer are laminated, and an outer edge of the first alignment mark layer is located inside an outer edge of the second alignment mark layer.

9. A alignment mark used for manufacturing an electrical connection device including a substrate including a first surface on which a first region and a second region, each having electric conductivity, are formed on a first surface, the first region and the second region being surrounded by an insulation region; a probe pad arranged on the substrate and having a structure in which a first pad layer and a second pad layer are laminated; and a probe arranged on an upper surface of the second pad layer of the probe pad, comprising:
a first alignment mark layer arranged in the second region of the substrate; and
a second alignment mark layer laminated on the first alignment mark layer; wherein
the first alignment mark layer and the second alignment mark layer have similar shapes when viewed from the lamination direction in which the first alignment mark layer and the second alignment mark layer are laminated, and the outer edge of the first alignment mark layer is located inside the outer edge of the second alignment mark layer.

10. The alignment mark according to claim 9, wherein
the second region and the second alignment mark layer have the same shape, and
the insulation region is exposed adjacent to an outer edge of the second alignment mark layer.

11. The alignment mark according to claim 9, wherein
the material for the first pad layer and the material for the first alignment mark layer are the same, and the first pad layer and the first alignment mark layer are arranged on the same plane level, and
the material for the second pad layer and the material for the second alignment mark layer are the same, and the second pad layer and the second alignment mark layer are arranged on the same plane level.

12. The alignment mark according to claim 9, wherein the first alignment mark layer and the second alignment mark layer have a cross shape when viewed from the lamination direction.

13. The alignment mark according to claim 9, wherein the material for the first alignment mark layer and the second alignment mark layer are copper.

14. The alignment mark according to claim 13, wherein a nickel layer and a gold layer are sequentially laminated on the surface of the second alignment mark layer.

15. A method of manufacturing an electrical connection device used for inspecting electrical characteristics of an inspection object, comprising:
preparing a substrate, in which a conductive layer is laminated on an insulation layer and is exposed as a first surface;
forming a probe pad by laminating a first pad layer and a second pad layer on a first region of the first surface;
forming an alignment mark by laminating a first alignment mark layer and a second alignment mark layer in a second region of the first surface separated from the first region;
removing the conductive layer from a remaining region of the first surface except the first region and the second region to expose the insulation layer; and
bonding a probe, which is to be connected to the inspection object, to the probe pad using the alignment mark; wherein
the first alignment mark layer and the second alignment mark layer have similar shapes when viewed from a lamination direction in which the first alignment mark layer and the second alignment mark layer are laminated, and an outer edge of the first alignment mark layer is located inside an outer edge of the second alignment mark layer.

16. The method of manufacturing an electrical connection device according to claim 15, wherein
the second region and the second alignment mark layer have the same shape when viewed from the lamination direction, and
the insulation region is exposed adjacent to an outer edge of the second alignment mark layer.

17. The method of manufacturing an electrical connection device according to claim 16, wherein the step of forming the probe pad and the alignment mark includes:
a stage of forming a first metal layer including the first pad layer of the probe pad, and the first alignment mark layer of the alignment mark, on the first surface of the substrate; and
a stage of laminating a second metal layer including the second pad layer arranged on a top surface of the first pad layer, and the second alignment mark layer arranged on a top surface of the first alignment mark layer, on the first metal layer.

18. The method of manufacturing an electrical connection device according to claim 17, wherein the material for the first metal layer and the second metal layer is copper.

19. The method of manufacturing an electrical connection device according to claim 18, further comprising a step of sequentially forming a nickel layer and a gold layer on an upper surface of the second metal layer.

20. The method of manufacturing an electrical connection device according to claim 15, wherein the first alignment mark layer and the second alignment mark layer have a cross shape when viewed from the lamination direction.

21. The method of manufacturing an electrical connection device according to claim 15, wherein the first pad layer and the second pad layer have the same shape when viewed from the lamination direction.
